(19) United States
(12) Patent Application Publication
(10) Pub. No.: US 2011/0304326 A1
(43) Pub. Date: Dec. 15, 2011

(54) MAGNETIC FIELD SENSOR INCLUDING MAGNETIC PARTICLES

(75) Inventor: Adarsh Sandhu, Tokyo (JP)

(73) Assignee: EMPIRE TECHNOLOGY DEVELOPMENT LLC

(21) Appl. No.: 13/160,984

(22) Filed: Jun. 15, 2011

Related U.S. Application Data
(63) Continuation of application No. 12/665,275, filed on Apr. 7, 2010.

(51) Int. Cl. G01R 33/02

(52) U.S. Cl. 324/214

(57) ABSTRACT

A magnetic field sensor which has a simple configuration and is capable of detecting a magnetic field with high sensitivity, including a vessel containing a dispersion in which magnetic particles are dispersed, a light source which irradiates the vessel with light, and light intensity measurement means arranged on an opposite side of the vessel from the light source for measuring the intensity of transmitted light having passed through the vessel, as needed.

### CROSS-REFERENCE TO RELATED APPLICATIONS

This application claims priority to U.S. application Ser. No. 12/665,275, which was filed on Apr. 7, 2010, pursuant to 35 U.S.C. §371 as a U.S. national-stage application that claims benefit of International Application No. PCT/JP2008/064821, which was filed on Aug. 20, 2008. Each of the above-referenced applications is incorporated herein by reference in its entirety.

### TECHNICAL FIELD

The present invention relates to a magnetic field sensor for detecting the intensity and/or direction of a magnetic field.

### BACKGROUND ART

An optical magnetic field sensor using the Faraday effect is known as a magnetic field sensor which detects the intensity of a magnetic field with high sensitivity (see, e.g., Patent Document 1). Such an optical magnetic field sensor is obtained by joining together a plurality of costly optical components, such as a Faraday component, a polarizer, an analyzer, and an optical lens, with high accuracy such that the optical axes of the optical components do not become misaligned with each other. The optical magnetic field sensor suffers from the problem of complex configuration and high cost.

[Patent Document 1] Japanese Patent Laid-Open No. 6182179

### SUMMARY

The present invention has as its object to provide a magnetic field sensor which has a simple configuration and is capable of detecting a magnetic field with high sensitivity.

The present inventors have found that if a dispersion in which particles with magnetism (magnetic particles) are dispersed are placed under the influence of a magnetic field, the magnetic particles align themselves and link together to form chains in a direction parallel to the direction of the magnetic field, resulting in a change in the light transmission of the dispersion, and that the change in the light transmission of the dispersion depends on the intensity of the magnetic field. The inventors have completed the present invention based on the findings.

In other words, the present invention is a magnetic field sensor including a vessel containing a dispersion in which magnetic particles are dispersed and a light source which irradiates the vessel with light.

### ADVANTAGE OF THE INVENTION

The present invention can detect a magnetic field with high sensitivity with a very simple configuration, a combination of a magnetic particle dispersion and a light source.

### BRIEF DESCRIPTION OF THE DRAWINGS

FIGS. 1A-1C are model views of a phenomenon utilized in the present invention;

FIG. 2 is a graph showing an example of the relationship between an intensity I of transmitted light having passed through a magnetic particle dispersion and an angle θ which a direction of irradiation with light used for measurement forms with the direction of a magnetic field; and

FIG. 3 is a schematic view of an example of a magnetic field sensor according to the present invention.

### DESCRIPTION OF SYMBOLS

1 dispersion medium

2 magnetic particle

3 direction of magnetic field

4 light from light source

4′ transmitted light

10 magnetic field sensor

11 dispersion medium

12 magnetic particle

14 light from light source

14′ transmitted light

15 vessel

16 light source

17 light intensity measurement means

18 rotating table

### DETAILED DESCRIPTION

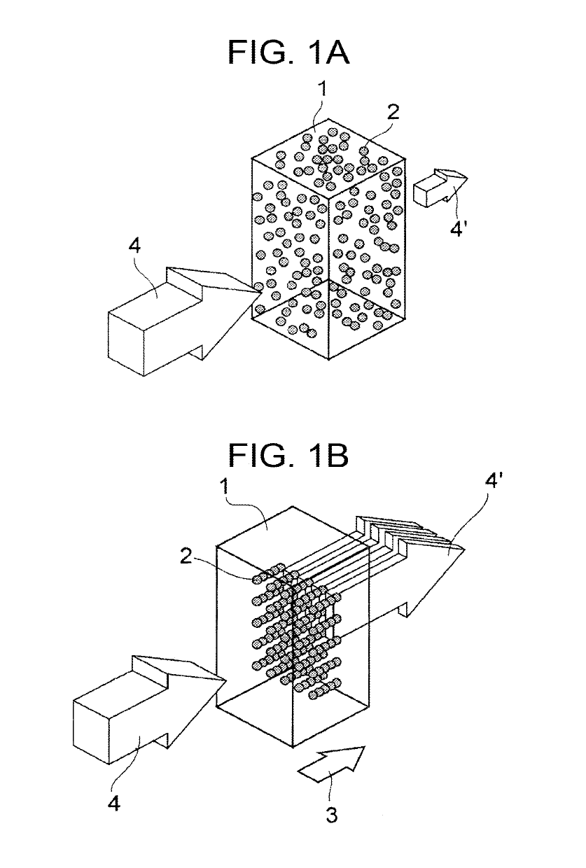

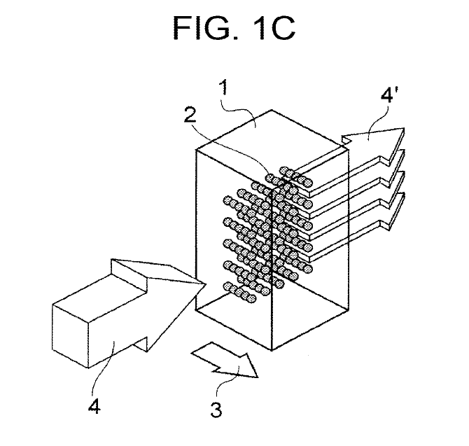

Although the best modes of the present invention will be described below, the present invention is not limited to these modes. The present invention utilizes a phenomenon in which if magnetic particles dispersed in a dispersion medium are placed under the influence of a magnetic field, the magnetic particles align themselves and link together in a direction parallel to the direction of the magnetic field to form chains. FIG. 1 show model views of the phenomenon. Of FIG. 1, FIG. 1A is a model view of magnetic particles dispersed in a dispersion medium if the magnetic particles are not affected by a magnetic field, and FIGS. 1B and 1C are model views of the magnetic particles dispersed in the dispersion medium if the magnetic particles are affected by the magnetic field.

Reference numeral 1 denotes the dispersion medium; 2, a magnetic particle; and 3, the direction of the magnetic field. In this case, the length of a formed chain of magnetic particles depends on the intensity of the magnetic field and tends to increase with an increase in the magnetic field intensity.

When a magnetic particle dispersion in which the magnetic particles 2 are aligned and are linked together parallel to the direction 3 of the magnetic field to form chains is irradiated with light 4 having a wavelength absorbed or reflected by the magnetic particles (FIGS. 1B and 1C), the intensity of transmitted light 4′ having passed through the magnetic particle dispersion is higher than that when the magnetic particles are not aligned (FIG. 1A) (that is, the light transmission of the magnetic particle dispersion becomes higher). In this case, the intensity of the transmitted light 4′ depends on the intensity of the magnetic field and tends to increase with an increase in the magnetic field intensity.

The intensity of the transmitted light 4′ having passed through the magnetic particle dispersion also depends on an angle 8 which a direction of irradiation with the light 4 forms with the direction 3 of the magnetic field. More specifically, the intensity of the transmitted light 4′ having passed through the magnetic particle dispersion is at its maximum when the direction of irradiation with the light 4 is parallel to the direction of the magnetic field (i.e., chains) (0=0° or) 180° and is at its minimum when the direction of irradiation with the light is perpendicular to the direction of the magnetic field (i.e., chains) (θ=90° or) 270°.

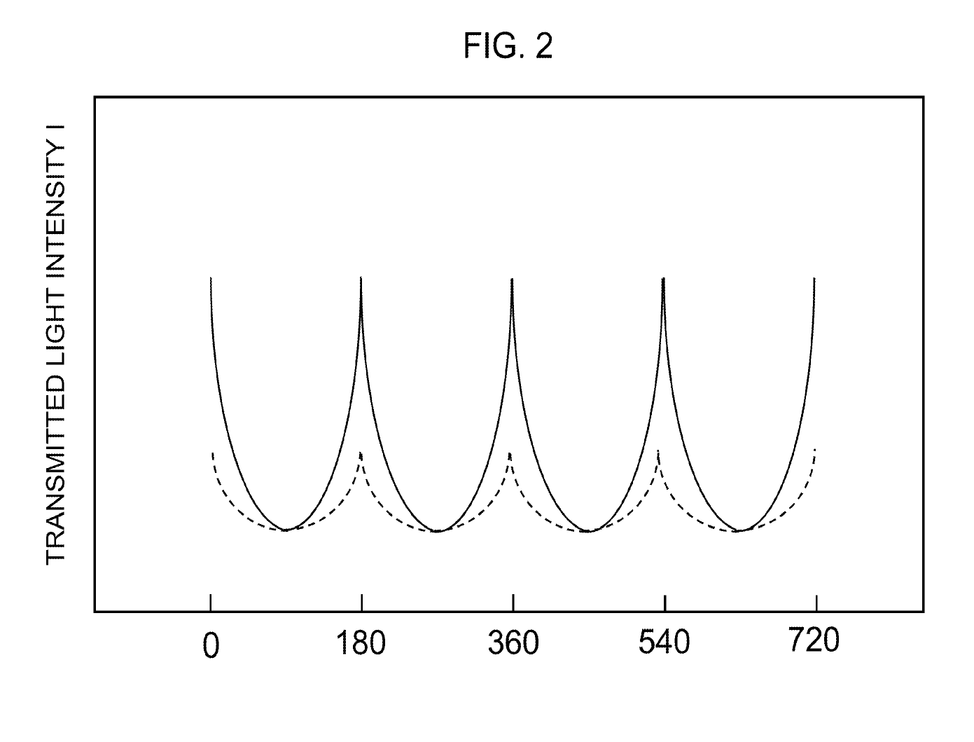

FIG. 2 shows an example of the relationship between the intensity of transmitted light having passed through a magnetic particle dispersion and an angle θ which a direction of irradiation with light used for measurement forms with the direction of a magnetic field. In FIG. 2, the ordinate of the graph represents an intensity I of transmitted light having passed through the magnetic particle dispersion, and the abscissa represents the angle θ which the direction of irradiation with light forms with the direction of the magnetic field. The solid line indicates data if the intensity of the magnetic field is x (Oe), and the dotted line indicates data if the magnetic field intensity is y (Oe) (x>y).

As shown in FIG. 2, the intensity of the transmitted light having passed through the magnetic particle dispersion changes with 0, reaches its maximal value at intervals of 180° starting from θ=0°, and reaches its minimal value at intervals of 180° starting from θ=90°. Additionally, the intensity of the transmitted light increases with an increase in magnetic field intensity. The tendency becomes much more noticeable at intervals of 180° starting from θ=0°.

A specific example of a method for detecting the intensity of a magnetic field utilizing the above described phenomenon will be described.

In the present invention, a magnetic particle dispersion placed under the influence of a magnetic field is irradiated with light from a light source, and the intensity of the magnetic field is determined on the basis of the intensity of transmitted light having passed through the magnetic particle dispersion.

If an accurate value of the intensity of a magnetic field is necessary, the accurate value can be detected by, for example, utilizing a calibration curve generated in advance using a magnetic field whose intensity is known. More specifically, a magnetic field sensor according to the present invention is arranged under the influence of a magnetic field whose intensity is known, for example, such that a direction of irradiation from a light source coincides with the direction of the magnetic field, the intensity of transmitted light having passed through a magnetic particle dispersion is measured, and a calibration curve indicating the relationship between the intensity of transmitted light and the intensity of a magnetic field is prepared in advance. The magnetic field sensor according to the present invention is then arranged under the influence of a magnetic field to be detected such that a direction of irradiation from the light source coincides with the direction of the magnetic field, in a similar manner to when the calibration curve is generated. After that, the intensity of transmitted light having passed the magnetic particle dispersion is measured, a result of the measurement is applied to the prepared calibration curve, and the intensity of the magnetic field is determined.

The direction of a magnetic field can be detected using a magnetic field sensor according to the present invention in the manner below.

As described above, the intensity of transmitted light having passed through a magnetic particle dispersion placed under the influence of a magnetic field is at its maximum when a direction of irradiation with light is parallel to the direction of the magnetic field (θ=0° or) 180°. Accordingly, if the intensity of transmitted light having passed through the magnetic particle dispersion is measured while the direction of irradiation with light is changed, under the influence of a magnetic field to be detected, and a direction of irradiation with the measured light when the intensity is at its maximum is identified, the direction or a direction which forms 180° with the direction is the direction of the magnetic field.

The configuration of a magnetic field sensor according to the present invention will now be described.

The magnetic field sensor according to the present invention includes a vessel containing a dispersion in which magnetic particles are dispersed and a light source which irradiates the vessel with light.

The magnetic particles are not particularly limited as long as they are particles which have magnetism and absorb or reflect light from a light source to be used. The magnetic particles may be solid or liquid.

Specific examples of the magnetic particles are ones obtained by dispersing magnetic powder among particles made of a polymeric material and ones obtained by applying magnetic powder to the surfaces of core particles made of a polymeric material. Specific examples of the magnetic power include, but are not limited to, iron oxides such as magnetite, hematite, and ferrite. Specific examples of the polymeric material include, but are not limited to, polystyrene, a styrenic copolymer, and polyester. The concentration of the magnetic power in the magnetic particles can be set to, for example, 1 to 10 g/cm3.

In order to increase the absorbance or reflectance for light from the light source to be used, the surfaces of the magnetic particles may be coated with a material having high absorbance or reflectance for light from the light source for measurement. Specific examples of the coating material include, but are not limited to, Au, etc.

The grain diameter of the magnetic particles is not particularly limited as long as the magnetic particles can be dispersed in a dispersion medium.

In general, stable dispersion is more feasible with magnetic particles as a dispersoid having a smaller grain diameter. In the present invention, the grain diameter of the magnetic particles may be, for example, about 0.1 to 50 ˜m. Note that the term grain diameter here refers to a Stokes' diameter measured by laser diffraction/light scattering.

The grain diameter of the magnetic powder included in the magnetic particles may be, for example, about 0.1 nm to 10 nm. If the grain diameter of the magnetic powder falls within the range, the magnetic powder exhibits superparamagnetism. If the grain diameter is too large, the magnetic powder tends to be ferromagnetic. In this case, the magnetic particles agglomerate and the solution can not serve as a dispersion.

The dispersion medium in the dispersion is not particularly limited as long as it allows the magnetic particles to be dispersed therein and can transmit light from the light source to be used.

Stable dispersion of the magnetic particles in the dispersion medium makes it possible to stably detect a magnetic field. Accordingly, the type of the dispersion medium may be appropriately selected to suit the magnetic particles used for realization of stable dispersion. A surface active agent can also be used to stabilize dispersion of the magnetic particles in the dispersion medium.

The dispersion medium with high light transmission for light from the light source to be used makes it possible to detect, with high sensitivity, a change in the light transmission of the dispersion caused by alignment of the magnetic particles. The type of the dispersion medium may be appropriately selected to suit the wavelength of the light source to be used.

Specific examples of the dispersion medium include, but are not limited to, organic solvents such as water, ethanol, etc.

The dispersion medium with a low viscosity has the advantage of facilitating movement (alignment and linking) of the magnetic particles placed under the influence of a magnetic field and shortening the time required for measurement. On the other hand, the dispersion medium with a high viscosity has the advantage of preventing alignment and linking of the magnetic particles caused by the influence of the magnetic field from being disturbed by external vibration or the like and allowing stable measurement.

The viscosity of the dispersion medium may be appropriately adjusted by, for example, selecting the type of the dispersion medium or adding a viscosity modifier to suit the application of the magnetic field sensor.

The concentration of the magnetic particles in the dispersion is not particularly limited. For example, the concentration may be set to 1 to 100 mg/ml.

The vessel for the magnetic particle dispersion is not particularly limited as long as it can hold the dispersion and can transmit light from the light source to be used.

The vessel with high light transmission for light from the light source to be used makes it possible to detect a change in the light transmission of the dispersion caused by alignment of the magnetic particles with high sensitivity. Accordingly, the type of the material for the vessel may be appropriately selected to suit the wavelength of the light source to be used. Specific examples of the material for the vessel include, but are not limited to, transparent materials such as glass, a light transmissive resin (e.g., an acrylic resin), etc.

There is no limitation on the shape of the vessel. Specific examples of the shape include, but are not limited to, a rectangular parallelepiped, a cylinder, etc. There is no limitation on the size of the vessel. For example, the thickness of the vessel may be reduced (by about several mm) in terms of reducing measurement noise.

The light source is not particularly limited as long as it can emit, at a detectable intensity, light having a wavelength which can pass through the vessel containing the dispersion. Specific examples of the light source include, but are not limited to, a laser light source and a diffuse light source such as an incandescent lamp or a fluorescent lamp.

The light source is installed in a place from which the light source can irradiate the vessel containing the magnetic particle dispersion with light. The distance between the vessel containing the dispersion and the light source or the position of the light source relative to the vessel containing the dispersion may be fixed for stable measurement.

The magnetic field sensor according to the present invention may further include light intensity measurement means for measuring the intensity of transmitted light having passed through the vessel, said means being arranged on the opposite side of the vessel from the light source.

The light intensity measurement means is not particularly limited as long as it can measure the intensity of transmitted light having passed through the vessel containing the magnetic particle dispersion.

The light intensity measurement means is installed at a position where it can receive transmitted light having passed through the vessel containing the magnetic particle dispersion, i.e., a position facing the light source across the vessel. The distance between the vessel containing the dispersion and the light intensity measurement means or the position of the light intensity measurement means relative to the vessel containing the dispersion may be fixed for stable measurement.

The magnetic field sensor according to the present invention may include determination means for determining the intensity of a magnetic field on the basis of the intensity of transmitted light measured by the light intensity measurement means. Storage means for retaining information on a calibration curve generated in advance may be connected to the determination means.

The magnetic field sensor according to the present invention may further include a rotating table for placing the vessel, the light source, and the light intensity measurement means, said table being rotatable about a vertical axis, in order to facilitate detection of the direction of a magnetic field.

Specific examples of a magnetic field sensor according to the present invention and a method for using the magnetic field sensor will now be described with reference to the drawing.

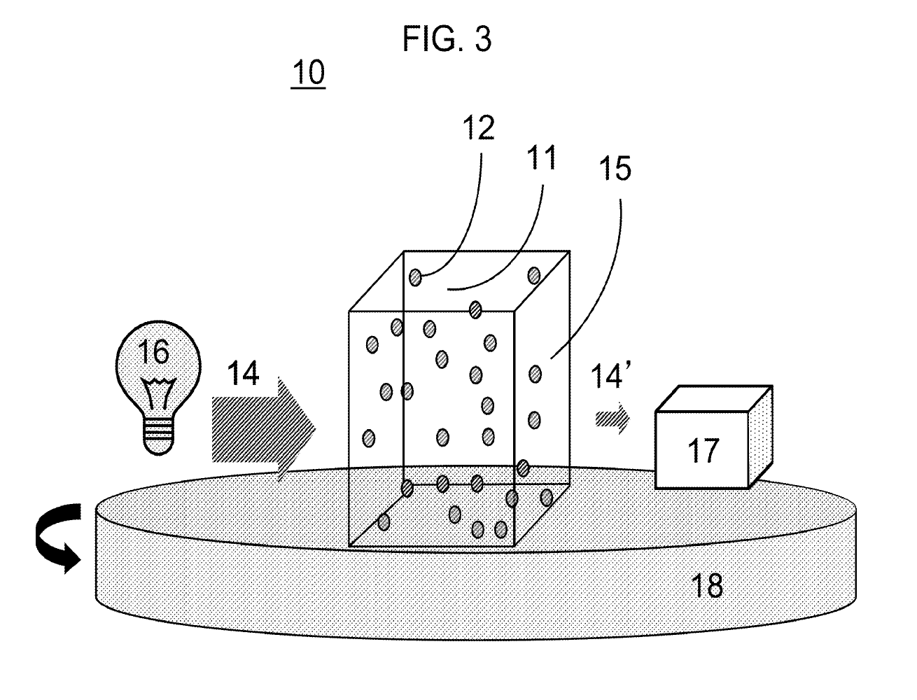

FIG. 3 is a schematic view of an example of a magnetic field sensor 10 according to the present invention. The magnetic field sensor is composed of a vessel 15 containing a magnetic particle dispersion obtained by dispersing magnetic particles 12 in a dispersion medium 11, a light source 16, light intensity measurement means 17, and a rotating table 18 for placing these components. An information processing unit 20 (not shown) is connected to the light intensity measurement means 17 with or without wires, as needed.

In the example in FIG. 3, magnetic beads made by Micromer (polystyrene fine particles among which FIG. 3 particles with an average grain diameter of 10 nm are dispersed, with an average grain diameter of 1.5 ˜m) are used as the magnetic particles 12, water is used as the dispersion medium 11 (the concentration of the magnetic particle dispersion is 25 mg/ml), a 12 mm wide by 12 mm deep by 45 mm high rectangular vessel made of acrylic resin is used as the vessel 15, and an incandescent lamp (a tungsten lamp) is used as a light source.

The information processing unit 20 is composed of storage means 21 for storing a transmitted light intensity I measured by the light intensity measurement means 17 and determination means 22 for determining the intensity of a magnetic field on the basis of the transmitted light intensity I. Calibration curve information storage means 23 is connected to the determination means 22. Information on a calibration curve generated by arranging the magnetic field detection portion 10 in a magnetic field whose intensity and direction are known such that the direction of irradiation from the light source 16 coincides with the direction of the magnetic field is retained in the calibration curve information storage means 23.

The magnetic field sensor 10 is installed at an arbitrary position in a magnetic field whose direction and intensity are unknown in an arbitrary orientation. The light source 16 is switched on, and the vessel 15 containing the magnetic particle dispersion is irradiated with light 14. An intensity I of transmitted light 14′ having passed through the vessels is measured by the light intensity measurement means 17 and is stored in the storage means 21. A direction of irradiation with the light 14 from the light source 16 is changed by rotating the rotating table 18 about the vertical axis only by, for example, 5°. The transmitted light intensity I at a rotation angle a=5° with respect to the position where the magnetic field sensor 10 was originally installed is measured and is stored in the storage means 21. This operation is repeated from a=0° to a=180°. A highest transmitted light intensity Imax (i.e., the transmitted light intensity when the direction of irradiation from the light source coincides with the direction of the magnetic field) is identified among obtained results. The intensity of the magnetic field is determined by the determination means 22 on the basis of Imax and the calibration curve information retained in the calibration curve information storage means 23.

A magnetic field sensor according to the present invention can be utilized for various applications requiring detection of the intensity and/or direction of a magnetic field, such as detection of an abnormality in, for example, a power line or a transformer substation, and nondestructive testing.

1-5. (canceled)

6. A magnetic field sensor comprising:
a vessel containing a dispersion in which magnetic particles are dispersed, wherein applying a magnetic field to the vessel causes the magnetic particles to form at least one chain aligned in a direction of the magnetic field;
a light source which irradiates the vessel with light;
a light intensity detector configured to measure an intensity of transmitted light having passed through the vessel, the light intensity detector being arranged on a side opposite to the light source with the vessel sandwiched therebetween; and
an information processing unit configured to determine an intensity of the magnetic field on the basis of the transmitted light.

7. The magnetic field sensor according to claim 6, wherein surfaces of the magnetic particles are coated with Au.

8. The magnetic field sensor according to claim 6, wherein a concentration of the magnetic particles in the dispersion is about 1 mg/mL to about 100 mg/mL.

9. The magnetic field sensor according to claim 25, wherein the magnetic powder includes an iron oxide.

10. The magnetic field sensor according to claim 25, wherein a concentration of the magnetic powder in the magnetic particles is about 1 g/cm³ to about 10 g/cm³.

11. The magnetic field sensor according to claim 25, wherein the polymeric material includes at least one member of the group consisting of polystyrene, styrenic copolymer, and polyester.

12. The magnetic field sensor according to claim 6, further including storage means operably coupled to the information processing unit and configured to store a magnetic field calibration curve.

13. The magnetic field sensor according to claim 12, wherein the magnetic field calibration curve is generated using a known magnetic field.

14. The magnetic field sensor according to claim 6, wherein the information processing unit is further configured to determine the direction of the magnetic field on the basis of the transmitted light.

15. A method of sensing a magnetic field, the method comprising:
providing a vessel containing a dispersion in which magnetic particles are dispersed;
applying the magnetic field to the vessel so as to cause the magnetic particles to form at least one chain aligned in a direction of the magnetic field;
irradiating the vessel with a light source;
measuring an intensity of light transmitted through the vessel; and
determining an intensity of the magnetic field on the basis of the intensity of light.

16. The method according to claim 15, wherein surfaces of the magnetic particles are coated with Au.

17. The method according to claim 15, wherein a concentration of the magnetic particles in the dispersion is about 1 mg/mL to about 100 mg/mL.

18. The method according to claim 24, wherein the magnetic powder includes an iron oxide.

19. The method according to claim 24, wherein a concentration of the magnetic powder in the magnetic particles is about 1 g/cm³ to about 10 g/cm³.

20. The method according to claim 24, wherein the polymeric material includes at least one member of the group consisting of polystyrene, styrenic copolymer, and polyester.

21. The method according to claim 15, further including storing a magnetic field calibration curve.

22. The method according to claim 21, further including generating the magnetic field calibration curve using a known magnetic field.

23. The method according to claim 15, further including detecting a direction of the magnetic field.

24. The method according to claim 15, wherein the magnetic particles include a polymeric material and magnetic powder dispersed in the polymeric material, the magnetic powder having a particle diameter of about 0.1 nm to about 10 nm.

25. The magnetic field sensor according to claim 6, wherein the magnetic particles include a polymeric material and magnetic powder dispersed in the polymeric material, the magnetic powder having a particle diameter of about 0.1 nm to about 10 nm.
